(19) United States
(12) Patent Application Publication
(10) Pub. No.: US 2024/0309508 A1
(43) Pub. Date: Sep. 19, 2024

(54) SUBSTRATE PROCESSING APPARATUS

(71) Applicant: TOKYO ELECTRON LIMITED, Tokyo (JP)

(72) Inventor: Tomoyuki NAGATA, Oshu City (JP)

(21) Appl. No.: 18/600,373

(22) Filed: Mar. 8, 2024

(30) Foreign Application Priority Data
Mar. 13, 2023 (JP) 2023-038364

(51) Int. Cl. C23C 16/455

(52) U.S. Cl. CPC C23C 16/45578

(57) ABSTRACT

A substrate processing apparatus includes: a first reaction tube of a vertical shape; and a gas injector configured to supply a gas to an interior of the first reaction tube, wherein the gas injector has a first tubular portion extending horizontally to pass through a sidewall of the first reaction tube, the first reaction tube has a support portion protruding toward a center of the first reaction tube below the first tubular portion, and the support portion is in contact with the gas injector to support the gas injector.

### CROSS-REFERENCE TO RELATED APPLICATION

This application is based upon and claims the benefit of priority from Japanese Patent Application No. 2023-038364, filed on Mar. 13, 2023, the entire contents of which are incorporated herein by reference.

### TECHNICAL FIELD

The present disclosure relates to a substrate processing apparatus.

### BACKGROUND

In a batch-type substrate processing apparatus, a technique is known in which gas is supplied into a processing container using a gas injector provided to pass through the processing container (e.g., see Patent Document 1).

### PRIOR ART DOCUMENT

### Patent Document

Patent Document 1: Japanese Laid-Open Patent Publication No. 2016-176584

### SUMMARY

According to one embodiment of the present disclosure, a substrate processing apparatus includes: a first reaction tube of a vertical shape; and a gas injector configured to supply a gas to an interior of the first reaction tube, wherein the gas injector has a first tubular portion extending horizontally to pass through a sidewall of the first reaction tube, the first reaction tube has a support portion protruding toward a center of the first reaction tube below the first tubular portion, and the support portion is in contact with the gas injector to support the gas injector.

### BRIEF DESCRIPTION OF DRAWINGS

The accompanying drawings, which are incorporated in and constitute a portion of the specification, illustrate embodiments of the present disclosure, and together with the general description given above and the detailed description of the embodiments given below, serve to explain the principles of the present disclosure.

FIG. 1 is a cross-sectional view showing a substrate processing apparatus according to a first embodiment.

FIG. 2 is an enlarged view of a portion of the substrate processing apparatus of FIG. 1.

FIG. 3 is a cross-sectional view taken in a direction of arrow III-III in FIG. 2.

FIG. 4 is a diagram showing a gas injector according to a first configuration example.

FIG. 5 is a diagram showing a gas injector according to a second configuration example.

FIG. 6 is a diagram showing a gas injector according to a third configuration example.

FIG. 7 is a cross-sectional view showing a substrate processing apparatus according to a second embodiment.

FIG. 8 is an enlarged view of a portion of the substrate processing apparatus of FIG. 7.

### DETAILED DESCRIPTION

Hereinafter, non-limitative exemplary embodiments of the present disclosure will now be described with reference to the accompanying drawings. In all the accompanying drawings, the same or corresponding members or components will be denoted by the same or corresponding reference numerals, and redundant explanations thereof will be omitted. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### First Embodiment

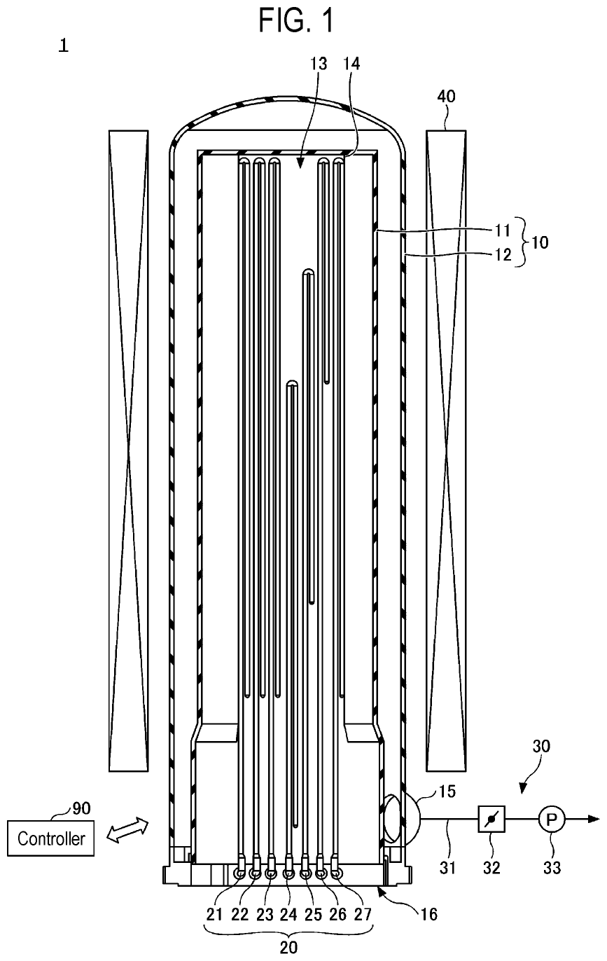

A substrate processing apparatus 1 according to a first embodiment will now be described with reference to FIG. 1. FIG. 1 is a cross-sectional view showing the substrate processing apparatus 1 according to the first embodiment.

The substrate processing apparatus 1 includes a processing container 10, a gas supplier 20, an exhauster 30, a heating part 40, and a controller 90.

The processing container 10 is a vertical reaction tube that has a double tube structure and extends in a vertical direction. The processing container 10 accommodates a substrate holder (not shown). The substrate holder holds substrates in a horizontal posture in a state in which the substrates are aligned in multiple stages in the vertical direction. The substrate holder is made of, for example, quartz. The substrate is, for example, a semiconductor wafer. The processing container 10 includes an inner tube 11 and an outer tube 12. The inner tube 11 has a substantially cylindrical shape with a ceiling and a lower end opening. The outer tube 12 covers the outside of the inner tube 11. The outer tube 12 has a substantially cylindrical shape with a ceiling and a lower end opening. The inner tube 11 and the outer tube 12 are arranged in a coaxial relationship with each other. The inner tube 11 and the outer tube 12 are made of, for example, quartz.

An accommodator 13 for accommodating a gas injector is formed in the vertical direction on one side of the inner tube 11. A portion of a sidewall of the inner tube 11 is protruded outward to form a convex portion 14, and an interior of the convex portion 14 is defined as the accommodator 13. A rectangular opening (not shown) is formed in the vertical direction on an opposite sidewall of the inner tube 11 facing the accommodator 13.

An exhaust port 15 is formed in the sidewall of the outer tube 12. A lid (not shown) is installed at an opening 16 of the lower end of the outer tube 12 via a sealing member such as an O ring. The lid may open and close the opening 16 and hermetically seals the opening 16.

The gas supplier 20 includes a plurality of gas injectors 21 to 27. The plurality of gas injectors 21 to 27 is arranged at intervals in a line along a circumferential direction of the processing container 10 in the accommodator 13. Each of the gas injectors 21 to 27 is connected to a gas source (not shown) via a gas introduction pipe 51 (FIG. 2). Various gases are introduced into each of the gas injectors 21 to 27 from the gas source via the gas introduction pipe 51. Each of the gas injectors 21 to 27 introduces various gases into the processing container 10. Various gases are selected according to processing to be performed within the processing container 10. Each of the gas injectors 21 to 27 is made of, for example, quartz.

Each of the gas injectors 21 to 27 is configured as a gas injector having a folded structure. However, a shape of each of the gas injectors 21 to 27 is not limited to the example shown in FIG. 1. Each of the gas injectors 21 to 27 does not need to have the folded structure. Each of the gas injectors 21 to 27 extends vertically within the inner tube 11 along an inner wall surface of the inner tube 11. Each of the gas injectors 21 to 27 is bent in an L shape at a bottom thereof and penetrates the sidewall of the outer tube 12. Each of the gas injectors 21 to 27 is folded in a U shape at a top thereof and then extends downward. Lengths of vertical portions of the gas injectors 21 to 23, 26, and 27, which extend in the vertical direction, are identical to each other. A length of a vertical portion of the gas injector 25, which extends in the vertical direction, is shorter than the lengths of the vertical portions of the gas injectors 21 to 23, 26, and 27. A length of a vertical portion of the gas injector 24, which extends in the vertical direction, is shorter than the length of the vertical portion of the gas injector 25. However, the lengths of the vertical portions of the gas injectors 21 to 27, which extend in the vertical direction, are not limited to the example shown in FIG. 1.

The vertical portion of each of the gas injectors 21 to 27 is provided with gas discharge holes (not shown). A plurality of gas discharge holes is provided at intervals in the vertical direction. Each of the gas injectors 21 to 27 discharges various gases into the processing container 10 via the plurality of gas discharge holes.

The exhauster 30 includes an exhaust pipe 31, a pressure regulating valve 32, and a vacuum pump 33. The exhaust pipe 31 is connected to the exhaust port 15. The pressure regulating valve 32 and the vacuum pump 33 are installed in the exhaust pipe 31. The pressure regulating valve 32 regulates an internal pressure of the processing container 10. The vacuum pump 33 exhausts gas within the processing container 10.

The heating part 40 is provided around the outer tube 12. The heating part 40 covers the surrounding of the outer tube 12. The heating part 40 has a substantially cylindrical shape. The heating part 40 includes a heater and a heat insulating material. The heater heats each substrate within the processing container 10. The heat insulating material is provided to cover the outer tube 12 and the heater from the outside. The heat insulating material prevents heat of the heater from leaking to the outside.

The controller 90 controls an operation of each part of the substrate processing apparatus 1. The controller 90 may be, for example, a computer. A computer program for executing an operation of each part of the substrate processing apparatus 1 is stored in a non-transitory computer-readable storage medium. The storage medium may be, for example, a flexible disk, a compact disc, a hard disk, a flash memory, a digital versatile disc (DVD), or the like.

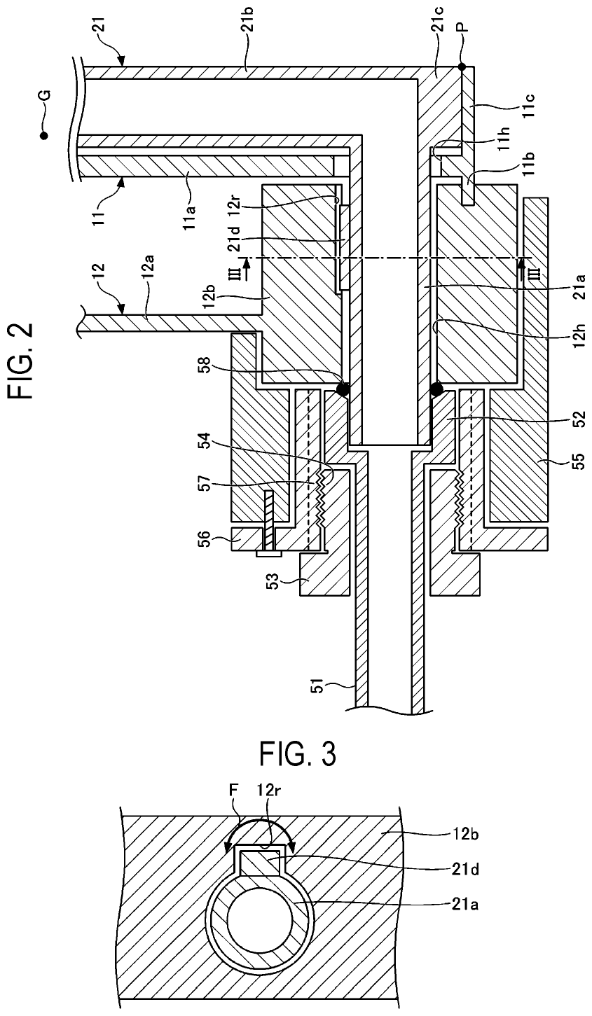

An installation structure of the gas injector 21 will now be described with reference to FIGS. 2 and 3. Installation structures of the gas injectors 22 to 27 may also be the same as the installation structure of the gas injector 21. FIG. 2 is an enlarged view of a portion of the substrate processing apparatus 1 of FIG. 1. FIG. 2 shows a state in which the gas injector 21 is installed in the processing container 10 and the gas introduction pipe 51 is connected to a bottom flange 55. FIG. 3 is a cross-sectional view taken in a direction of arrow III-III in FIG. 2.

The inner tube 11 has a cylindrical portion 11a, a flange portion 11b, and a support portion 11c. The cylindrical portion 11a has a substantially cylindrical shape with a ceiling. A through-hole 11h is provided in a lower portion of the cylindrical portion 11a. The gas injector 21 is inserted into the through-hole 11h. An inner diameter of the through-hole 11h may be slightly larger than an outer diameter of the gas injector 21. In this case, an installation tolerance of the gas injector 21 may be allowed. The flange portion 11b protrudes outward from an outer wall surface of the cylindrical portion 11a below the through-hole 11h and is fixed to a flange portion 12b of the outer tube 12. Thus, the inner tube 11 is supported by the outer tube 12 below the through-hole 11h. The flange portion 11b is formed integrally with, for example, the cylindrical portion 11a. The flange portion 11b may be formed separately from the cylindrical portion 11a. The support portion 11c protrudes inward from an inner wall surface of the cylindrical portion 11a below the through-hole 11h, and comes into contact with the gas injector 21 to support the gas injector 21. The support portion 11c contacts the gas injector 21 at a position overlapping a second tubular portion 21b of the gas injector 21, for example, in a plan view from above. The support portion 11c is formed integrally with, for example, the cylindrical portion 11a. The support portion 11c may be formed separately from the cylindrical portion 11a.

The outer tube 12 has a cylindrical portion 12a and the flange portion 12b. The cylindrical portion 12a has a substantially cylindrical shape with a ceiling. The flange portion 12b is provided at a lower portion of the cylindrical portion 12a. The flange portion 12b is formed integrally with, for example, the cylindrical portion 12a. The flange portion 12b may be formed separately from the cylindrical portion 12a. A through-hole 12h is provided in the flange portion 12b. The through-hole 12h extends horizontally. The through-hole 12h is provided at the same position as the through-hole 11h in a vertical direction and a circumferential direction of the processing container 10. The gas injector 21 is inserted into the through-hole 12h with a gap with respect to an inner wall surface of the through-hole 12h. An inner diameter of the through-hole 12h may be slightly larger than an outer diameter of the gas injector 21. In this case, the installation tolerance of the gas injector 21 may be allowed. A notch 12r is provided, for example, in an upper portion of the inner wall surface of the through-hole 12h. The notch 12r extends from an end portion of the through-hole 12h on a central side of the processing container 10 in a longitudinal direction of the through-hole 12h. The notch 12r is brought into contact with a second protrusion 21d when a force of rotating around a tube axis of a first tubular portion 21a (see arrow F in FIG. 3) acts on the gas injector 21, thereby functioning as a restrictor that restricts the rotation of the gas injector 21 around the tube axis of the first tubular portion 21a.

The gas injector 21 includes the first tubular portion 21a, the second tubular portion 21b, a first protrusion 21c, and the second protrusion 21d.

The first tubular portion 21a is inserted into the through-hole 11h and the through-hole 12h. The first tubular portion 21a passes through the cylindrical portion 11a and the flange portion 12b to extend horizontally. The first tubular portion 21a includes a gas flow path formed therein to allow gas to flow therethrough.

The second tubular portion 21b extends vertically within the inner tube 11 along an inner wall surface of the cylindrical portion 11a. The second tubular portion 21b includes a gas flow path formed therein to allow gas to flow therethrough. The gas flow path of the second tubular portion 21b communicates with the gas flow path of the first tubular portion 21a. The second tubular portion 21b is formed integrally with, for example, the first tubular portion 21a. However, the second tubular portion 21b may be formed separately from the first tubular portion 21a and may be bonded with the first tubular portion 21a by welding or the like.

The first protrusion 21c protrudes downward from a lower end of the second tubular portion 21b and is supported by the support portion 11c. In this case, a horizontal distance from a gravity center G of the gas injector 21 to the center of the processing container 10 is longer than a horizontal distance from a support point P of the gas injector 21 to the center of the processing container 10. Thus, a force that causes the gas injector 21 to tilt toward the center of the processing container 10 is not generated due to the weight of the gas injector 21. Therefore, it is possible to suppress the gas injector 21 from falling toward the center of the processing container 10. The first protrusion 21c has a flat surface, a lower surface facing an upper surface of the support portion 11c, and is configured to be in surface contact with the support portion 11c. However, the first protrusion 21c only needs to be brought into contact with at least a portion of the support portion 11c. For example, the first protrusion 21c may be configured to be brought into point contact with the support portion 11c. For example, the first protrusion 21c is formed integrally with the first tubular portion 21a and the second tubular portion 21b. However, the first protrusion 21c may be formed separately from the first tubular portion 21a and the second tubular portion 21b and may be bonded to the first tubular portion 21a and the second tubular portion 21b by welding or the like.

The second protrusion 21d protrudes radially outward from an outer wall surface of the first tubular portion 21a. The second protrusion 21d is provided at a position corresponding to the notch 12r of the flange portion 12b in a state in which the gas injector 21 is installed. The second protrusion 21d is brought into contact with the notch 12r when the force of rotating around the tube axis of the first tubular portion 21a acts on the gas injector 21, thereby restricting the rotation of the gas injector 21 around the tube axis of the first tubular portion 21a. The second protrusion 21d is formed separately from, for example, the first tubular portion 21a, and is bonded to the first tubular portion 21a by welding or the like. However, the second protrusion 21d may be formed integrally with the first tubular portion 21a.

The gas introduction pipe 51 is a pipe provided to introduce gas into the processing container 10 from the gas source (not shown). The gas introduction pipe 51 has one end connected to the gas source and the other end connected to the processing container 10. A retainer 52 is connected to the other end (tip) of the gas introduction pipe 51. A nut 53 is provided around a thin portion of the retainer 52. The tip portion of the retainer 52 has approximately the same diameter as that of the nut 53 and restricts the tip portion of the retainer 52 from being separated from the nut 53. A male screw portion 54 is provided at the tip portion of the nut 53.

The bottom flange 55 is provided to cover the flange portion 12b from above and below and from the sides. The bottom flange 55 is a gas introduction portion that introduces gas into the processing container 10 and may be provided at a predetermined location of the processing container 10. The bottom flange 55 is provided with a port block 56.

The port block 56 functions as a relay connection member when the gas introduction pipe 51 is connected to the bottom flange 55. The port block 56 includes a connection mechanism to which the gas introduction pipe 51 may be connected. For example, the port block 56 is configured to have an opening into which a tip of the gas introduction pipe 51 may be inserted. Further, the port block 56 may have a fitting structure or a screw fastening structure such as a screw so that the tip of the gas introduction pipe 51 inserted to the opening may be fixedly connected. A female screw portion 57 in which a thread is formed is provided on an inner wall surface of the opening of the port block 56. The gas introduction pipe 51 is connected to the port block 56 by screwing the female screw portion 57 of the port block 56 and the male screw portion 54 of the nut 53. In this case, as the nut 53 rotates, a forward force is applied to the retainer 52 so as to press an O ring 58.

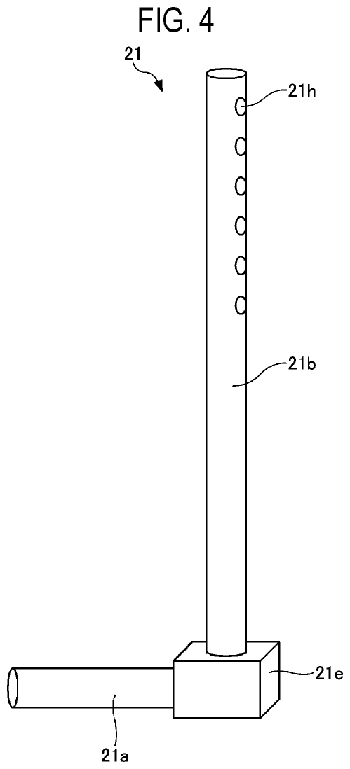

A specific configuration example of the gas injector 21 will now be described with reference to FIGS. 4 to 6. The gas injectors 22 to 27 may also have the same configuration as that of the gas injector 21.

FIG. 4 is a diagram showing a gas injector 21 according to a first configuration example. As shown in FIG. 4, the gas injector 21 according to the first configuration example includes the first tubular portion 21a, the second tubular portion 21b, and a block member 21e.

The first tubular portion 21a, the second tubular portion 21b, and the block member 21e are formed separately from each other. Each of the first tubular portion 21a and the second tubular portion 21b are welded to the block member 21e. Thus, the first tubular portion 21a and the second tubular portion 21b are connected to each other via the block member 21e. The block member 21e has a flat lower surface. The gas injector 21 is supported by the lower surface of the block member 21e in contact with an upper surface of the support portion 11c. The block member 21e functions as the first protrusion 21c described above. A plurality of gas discharge holes 21h is provided in the second tubular portion 21b at intervals in the vertical direction.

The gas injector 21 according to the first configuration example transports gas introduced into the first tubular portion 21a from the gas introduction pipe 51 to the second tubular portion 21b via the block member 21e and discharges the gas from the plurality of gas discharge holes 21h into the processing container 10.

FIG. 5 is a diagram showing a gas injector 21 according to a second configuration example. As shown in FIG. 5, the gas injector 21 according to the second configuration example includes a bend tube 21f instead of the block member 21e shown in FIG. 4.

The bend tube 21f has a right-angled bend shape. One end of the bend tube 21f extends horizontally and is connected to the first tubular portion 21a. The other end of the bend tube 21f extends vertically and is connected to the second tubular portion 21b. The gas injector 21 according to the second configuration example is supported by the bend tube 21f in contact with the support portion 11c. The bend tube 21f functions as the first protrusion 21c described above.

The gas injector 21 according to the second configuration example transports gas introduced into the first tubular portion 21a from the gas introduction pipe 51 to the second tubular portion 21b via the bend tube 21f, and discharges the gas from the plurality of gas discharge holes 21h into the processing container 10.

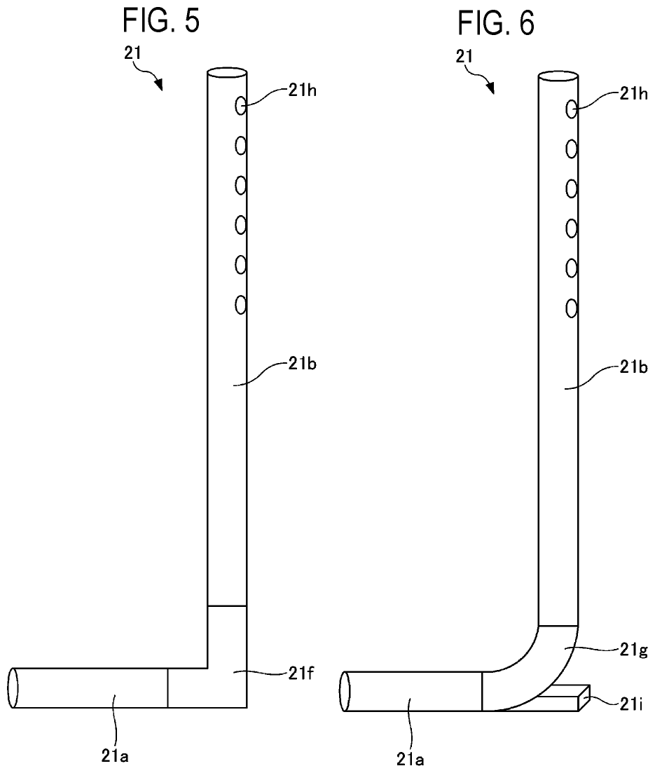

FIG. 6 is a diagram showing a gas injector 21 according to a third configuration example. As shown in FIG. 6, the gas injector 21 according to the third configuration example includes a bend tube 21g and a support plate 21i instead of the block member 21e shown in FIG. 4.

The bend tube 21g has an R-bent shape. One end of the bend tube 21g extends horizontally and is connected to the first tubular portion 21a by welding or the like. The other end of the bend tube 21g extends vertically and is connected to the second tubular portion 21b by welding or the like.

The support plate 21i is fixed to a lower portion of the bend tube 21g by welding or the like. The support plate 21i has a lower surface facing an upper surface of the support portion 11c, and is supported by the lower surface being in contact with the upper surface of the support portion 11c. The support plate 21i functions as the first protrusion 21c described above.

The gas injector 21 according to the third configuration example transports gas introduced into the first tubular portion 21a from the gas introduction pipe 51 to the second tubular portion 21b via the bend tube 21g, and discharges the gas from the plurality of gas discharge holes 21h into the processing container 10.

As described above, according to the substrate processing apparatus 1 of the first embodiment, the gas injector 21 is supported by the support portion 11c that protrudes inward from the inner wall surface of the cylindrical portion 11a below the through-hole 11h . . . . In this case, the horizontal distance from the gravity center G of the gas injector 21 to the center of the processing container 10 is longer than the horizontal distance from the support point P of the gas injector 21 to the center of the processing container 10. Thus, the force that causes the gas injector 21 to tilt toward the center of the processing container 10 is not generated due to the weight of the gas injector 21. Therefore, it is possible to suppress the gas injector 21 from falling toward the center of the processing container 10.

On the other hand, when the gas injector 21 is not supported by the support portion 11c, the support point P of the gas injector 21 is located inside the flange portion 12b. In this case, the horizontal distance from the gravity center G of the gas injector 21 to the center of the processing container 10 is shorter than the horizontal distance from the support point P of the gas injector 21 to the center of the processing container 10. As a result, the gas injector 21 may fall down by the force that causes the gas injector 21 to tilt toward the center of the processing container 10 due to the weight of the gas injector 21.

### Second Embodiment

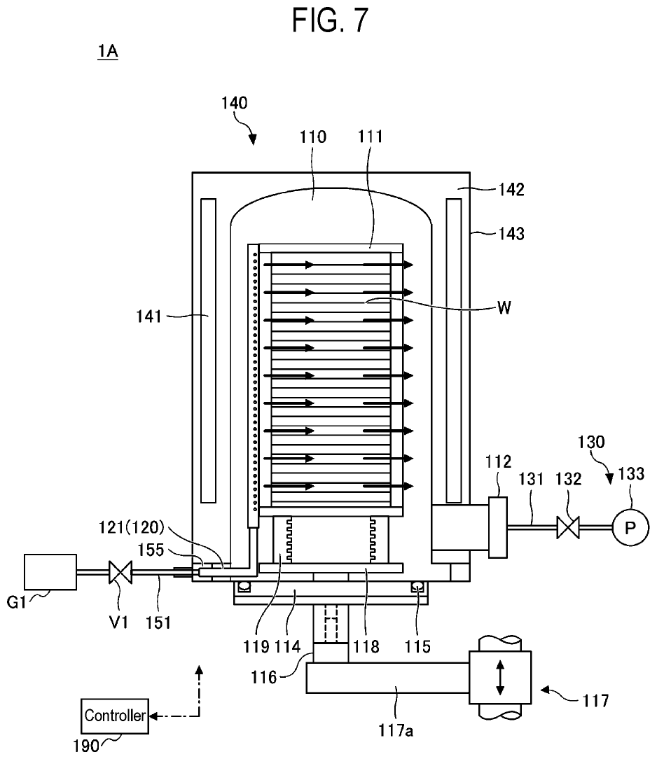

A substrate processing apparatus 1A according to a second embodiment will now be described with reference to FIG. 7. FIG. 7 is a cross-sectional view showing the substrate processing apparatus 1A according to the second embodiment. As shown in FIG. 7, the substrate processing apparatus 1A differs from the substrate processing apparatus 1 in that the substrate processing apparatus 1A has a single tube structure. Hereinafter, a description will be given focusing on differences from the substrate processing apparatus 1.

The substrate processing apparatus 1A includes a processing container 110, a gas supplier 120, an exhauster 130, a heating part 140, and a controller 190.

The processing container 110 is a vertical reaction tube that has a single tube structure and extends in a vertical direction. The processing container 110 is made of, for example, quartz. The processing container 110 accommodates a substrate holder 111. The substrate holder 111 holds substrates W in a horizontal posture in a state in which the substrates W are aligned in multiple stages in the vertical direction. The substrate holder 111 is made of, for example, quartz. The substrate W is, for example, a semiconductor wafer. An exhaust port 112 is formed below the processing container 110. The processing container 110 has a lower end opening. Loading and unloading of the substrate holder 111 on which the substrates W is placed are performed via the lower end opening of the processing container 110. The lower end of the processing container 110 is supported by a bottom flange 155. The bottom flange 155 is a place to which the gas injector 121 is attached.

A lid 114 is provided below the processing container 110. The lid 114 hermetically seals the lower end opening of the processing container 110 via a sealing member 115 such as an O ring. A rotational shaft 116 is provided to pass through the center of the lid 114 via a magnetic fluid seal (not shown). A lower portion of the rotational shaft 116 is rotatably supported by an arm 117a of a lifting mechanism 117 including a boat elevator. A rotational plate 118 is provided at an upper end of the rotational shaft 116. The rotational plate 118 supports a stage 119. The stage 119 supports the substrate holder 111. The rotational plate 118 and the stage 119 are made of, for example, quartz. The lifting mechanism 117 raises and lowers the substrate holder 111 and the lid 114 together and rotates the substrate holder 111, the rotational plate 118, and the stage 119 together.

Therefore, the lid 114 is configured to be raised and lowered while supporting the substrate holder 111 on which the substrates W are placed, and is configured to seal the lower end opening of the processing container 110 while supporting the substrate holder 111. Therefore, loading of the substrate holder 111 into the processing container 110 and unloading of the substrate holder 111 from the processing container 110 are performing by raising and lowering the lid 114 in a state in which the substrate holder 111 is supported above the lid 114.

The gas supplier 120 includes a gas injector 121. The gas injector 121 supplies various gases into the processing container 110. The gas injector 121 is inserted from an inner side of the processing container 110 into a through-hole provided at a lower end of the processing container 110 and a gas introduction port provided in the bottom flange 155. The gas injector 121 extends vertically along an inner wall surface of the processing container 110, and is bent in an L shape at the bottom to extend horizontally. A gas introduction pipe 151 is connected to a tip of a horizontally extending portion of the gas injector 121. The gas introduction pipe 151 is provided with a gas source G1 and a valve V1 in this order from an upstream side. Gas from the gas source G1 is introduced into the gas injector 121 via the gas introduction pipe 151. The gas injector 121 supplies various gases into the processing container 110 from a plurality of gas discharge holes provided in a vertically extending portion of the gas injector 121. The gas injector 121 is made of, for example, quartz. The gas supplier 120 may further include one or more gas injectors separately from the gas injector 121.

The exhauster 130 includes an exhaust pipe 131, a pressure regulating valve 132, and a vacuum pump 133. The exhauster 130 is connected to an exhaust port 112. The pressure regulating valve 132 and the vacuum pump 133 are installed in the exhaust pipe 131. The pressure regulating valve 132 regulates an internal pressure of the processing container 110. The vacuum pump 133 exhausts gas within the processing container 110.

The heating part 140 is provided around the processing container 110. The heating part 140 covers the processing container 110. The heating part 140 has a substantially cylindrical shape. The heating part 140 includes a heater 141, a heat insulating material 142, and a housing 143. The heater 141 heats each substrate W within the processing container 110. The heat insulating material 142 is provided so as to cover the processing container 110 and the heater 141 from the outside. The heat insulating material 142 prevents heat of the heater 141 from leaking to the outside. The housing 143 covers the heat insulating material 142. The interior of the housing 143 is filled with the heat insulating material 142 to suppress heat emitted to the outside.

The controller 190 controls an operation of each part of the substrate processing apparatus 1A. The controller 190 may be, for example, a computer. A computer program for executing the operation of each part of the substrate processing apparatus 1A is stored in a non-transitory computer-readable storage medium. The storage medium may be, for example, a flexible disk, a compact disc, a hard disk, a flash memory, a DVD, or the like.

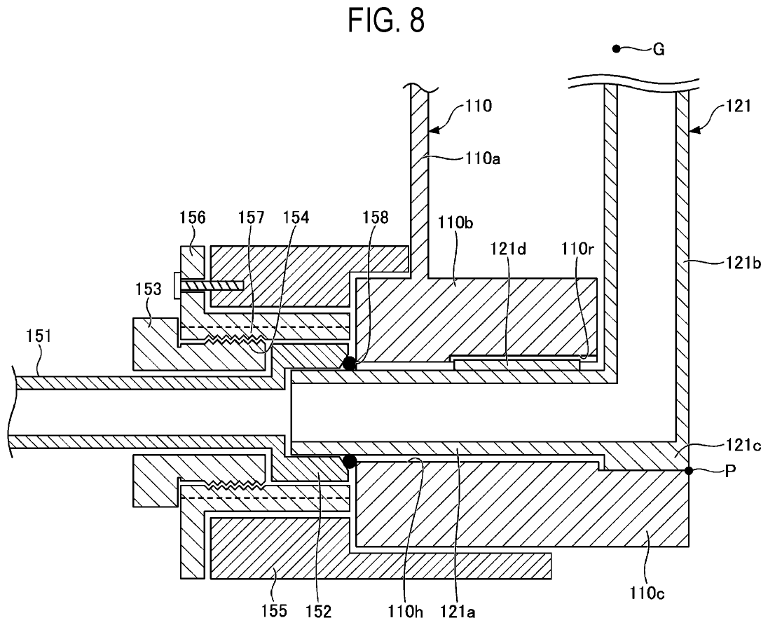

An installation structure of the gas injector 121 will now be described with reference to FIG. 8. FIG. 8 is an enlarged view of a portion of the substrate processing apparatus 1A of FIG. 7. FIG. 8 shows a state in which the gas injector 121 is installed in the processing container 110 and the gas introduction pipe 151 is connected to the bottom flange 155.

The processing container 110 has a cylindrical portion 110a, a flange portion 110b, and a support portion 110c. The cylindrical portion 110a has a substantially cylindrical shape with a ceiling. The flange portion 110b is provided at a lower portion of the cylindrical portion 110a. For example, the flange portion 110b is formed integrally with the cylindrical portion 110a. The flange portion 110b may be formed separately from the cylindrical portion 110a. A through-hole 110h is provided in the flange portion 110b. The gas injector 121 is inserted into the through-hole 110h with a gap with respect to an inner wall surface of the through-hole 110h. An inner diameter of the through-hole 110h may be slightly larger than an outer diameter of the gas injector 121. In this case, the installation tolerance of the gas injector 121 may be allowed. The notch 110r is provided, for example, at the top of an inner wall surface of the through-hole 110h. The notch 110r extends from an end portion of the through-hole 110h on a center side of the processing container 110 in a longitudinal direction of the through-hole 110h. The notch 110r is brought into contact with the second protrusion 121d when the force of rotating around the tube axis of the first tubular portion 121a acts on the gas injector 121, thereby functioning as a restrictor that restricts the rotation of the gas injector 121 around the tube axis of the first tubular portion 121a.

The support portion 110c protrudes inward from an inner wall surface of the flange portion 110b below the through-hole 110h, and is brought into contact with the gas injector 121 to support the gas injector 121. The support portion 110c is brought into contact with the gas injector 121 at a position overlapping the second tubular portion 121b of the gas injector 121, for example, in a plan view from above. The support portion 110c is formed integrally with, for example, the cylindrical portion 110a. The support portion 110c may be formed separately from the cylindrical portion 110a.

The gas injector 121 includes the first tubular portion 121a, the second tubular portion 121b, a first protrusion 121c, and the second protrusion 121d.

The first tubular portion 121a is inserted into the through-hole 110h. The first tubular portion 121a extends horizontally to pass through the flange portion 110b. The first tubular portion 121a has a gas flow path formed therein to allow gas to flow therethrough.

The second tubular portion 121b extends vertically within the inner tube 11 along an inner wall surface of the cylindrical portion 110a. The second tubular portion 121b has a gas flow path formed therein to allow gas to flow therethrough. The gas flow path of the second tubular portion 121b communicates with the gas flow path of the first tubular portion 121a. The second tubular portion 121b is formed integrally with, for example, the first tubular portion 121a. However, the second tubular portion 121b may be formed separately from the first tubular portion 121a and may be bond to the first tubular portion 121a by welding or the like.

The first protrusion 121c protrudes downward from a lower end of the second tubular portion 21b and is supported by the support portion 110c. In this case, the horizontal distance from the gravity center G of the gas injector 121 to the center of the processing container 110 is longer than the horizontal distance from the support point P of the gas injector 121 to the center of the processing container 110. Thus, the force that causes the gas injector 121 to tilt toward the center of the processing container 110 is not generated due to the weight of the gas injector 121. This makes it possible to suppress the gas injector 21 from falling toward the center of the processing container 110. The first protrusion 121c has a flat surface, a lower surface facing an upper surface of the support portion 110c, and is configured to be in surface contact with the support portion 110c. However, the first protrusion 121c only needs to be brought into contact with at least a portion of the support portion 110c. For example, the first protrusion 121c may be configured to be in point contact with the support portion 110c.

The second protrusion 121d protrudes radially outward from an outer wall surface of the first tubular portion 121a. The second protrusion 121d is provided at a position corresponding to the notch 110r of the flange portion 110b in a state in which the gas injector 121 is installed. The second protrusion 121d comes into contact with the notch 110r when the force of rotating around the tube axis of the first tubular portion 121a acts on the gas injector 121, thereby restricting the rotation of the gas injector 121 around the tube axis of the first tubular portion 121a.

The gas introduction pipe 151, a retainer 152, a nut 153, a male screw portion 154, the bottom flange 155, a port block 156, a female screw portion 157, and an O ring 158 may be the same configurations as the gas introduction pipe 51, the retainer 52, the nut 53, the male screw portion 54, the bottom flange 55, the port block 56, the female screw portion 57, and the O ring 58, respectively.

A specific configuration of the gas injector 121 may be the same as that of the gas injector 21 shown in FIGS. 4 to 6, for example.

As described above, according to the substrate processing apparatus 1A of the second embodiment, the gas injector 121 is supported by the support portion 110c that protrudes inward from an inner wall surface of the flange portion 110b below the through-hole 110h . . . . In this case, the horizontal distance from the gravity center G of the gas injector 121 to the center of the processing container 110 is longer than the horizontal distance from the support point P of the gas injector 121 to the center of the processing container 110. Thus, the force that causes the gas injector 121 to tilt toward the center of the processing container 110 is not generated due to the weight of the gas injector 121. This makes it possible to suppress the gas injector 121 from falling toward the center of the processing container 110.

On the other hand, when the gas injector 121 is not supported by the support portion 110c, the support point P of the gas injector 121 is located inside the flange portion 110b. In this case, the horizontal distance from the gravity center G of the gas injector 121 to the center of the processing container 110 is shorter than the horizontal distance from the support point P of the gas injector 121 to the center of the processing container 110. As a result, the gas injector 121 may fall down by the force that causes the gas injector 21 to tilt toward the center of the processing container 10 due to the weight of the gas injector 21.

According to the present disclosure in some embodiments, it is possible to suppress a gas inject from falling down.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus, comprising:
a first reaction tube of a vertical shape; and
a gas injector configured to supply a gas to an interior of the first reaction tube,
wherein the gas injector has a first tubular portion extending horizontally to pass through a sidewall of the first reaction tube,
wherein the first reaction tube has a support portion protruding toward a center of the first reaction tube below the first tubular portion, and
wherein the support portion is in contact with the gas injector to support the gas injector.

2. The substrate processing apparatus of claim 1, wherein the gas injector has a second tubular portion extending vertically along an inner wall surface of the first reaction tube in the interior of the first reaction tube, and
wherein the support portion is in contact with the gas injector at a position overlapping the second tubular portion in a plan view from above.

3. The substrate processing apparatus of claim 1, wherein the support portion is in surface contact with the gas injector.

4. The substrate processing apparatus of claim 1, wherein the first tubular portion has a protrusion protruding radially outward from an outer wall surface of the first tubular portion, and
wherein the first reaction tube includes a restrictor which is brought into contact with the protrusion to restrict a rotation of the gas injector around a tube axis of the first tubular portion.

5. The substrate processing apparatus of claim 1, further comprising: a second reaction tube provided around the first reaction tube,
wherein the second reaction tube is configured to support the first reaction tube below the first tubular portion.

6. The substrate processing apparatus of claim 2, further comprising: a second reaction tube provided around the first reaction tube,
wherein the second reaction tube is configured to support the first reaction tube below the first tubular portion.
